(19) United States
(12) Patent Application Publication
(10) Pub. No.: US 2025/0320066 A1
(43) Pub. Date: Oct. 16, 2025

(54) WAFER HANDLING APPARATUS AND METHOD FOR MONITORING WAFER HANDLING APPARATUS

(71) Applicant: NANYA TECHNOLOGY CORPORATION, New Taipei City (TW)

(72) Inventors: Yi-Wen LIU, New Taipei City (TW); Jih-Cheng HUANG, New Taipei City (TW)

(21) Appl. No.: 18/634,988

(22) Filed: Apr. 14, 2024

(51) Int. Cl. B65G 43/02; H01L 21/687

(52) U.S. Cl. CPC B65G 43/02; H01L 21/68707; B65G 2203/0266

(57) ABSTRACT

A wafer handling apparatus includes a housing, a load port, a robotic arm, an air particle detector and a control system. The load port is mounted on a side of the housing and configured to receive a wafer container. The wafer container is configured to accommodate a semiconductor wafer. The robotic arm is disposed inside the housing and is configured to transfer the semiconductor wafer into or out of the wafer container. The air particle detector is disposed inside the housing and configured to provide at least one detection signal indicative of a number of particles in air. The control system is communicably coupled to the air particle detector. The control system is configured to receive the detection signal and perform at least one protection action based on the detection signal.

### BACKGROUND

### Technical Field

The present disclosure relates to a wafer handling apparatus and a method for monitoring a wafer handling apparatus.

### Description of Related Art

A faulty wafer processing machine could generate contaminants and cause contamination of wafers. Currently, wafer contamination can only be detected at a wafer measurement machine, and by the time the contaminated wafer is detected by the wafer measurement machine, many wafers would have entered the faulty wafer processing machine and become contaminated as well. Moreover, when wafer contamination occurs, engineers have to manually examine several wafer processing machines to identify the faulty wafer processing machine and identify the cause of the anomaly. This procedure is time-consuming and could cause a significant delay of wafer production.

### SUMMARY

An aspect of the disclosure is to provide a wafer handling apparatus that can perform real-time environmental monitoring of the interior of the wafer handling apparatus.

In accordance with an embodiment of the present disclosure, a wafer handling apparatus includes a housing, a load port, a robotic arm, an air particle detector and a control system. The load port is mounted on a side of the housing and configured to receive a wafer container. The wafer container is configured to accommodate a semiconductor wafer. The robotic arm is disposed inside the housing and is configured to transfer the semiconductor wafer into or out of the wafer container. The air particle detector is disposed inside the housing and configured to provide at least one detection signal indicative of a number of particles in air. The control system is communicably coupled to the air particle detector. The control system is configured to receive the detection signal and perform at least one protection action based on the detection signal.

In one or more embodiments of the present disclosure, the air particle detector is located underneath a path along which the robotic arm moves the semiconductor wafer.

In one or more embodiments of the present disclosure, the air particle detector is located underneath or next to a movable mechanical part of the wafer handling apparatus.

In one or more embodiments of the present disclosure, the load port includes a door opening device. The door opening device is configured to open a door of the wafer container received by the load port. The movable mechanical part includes the door opening device, and the air particle detector is located underneath or next to the door opening device.

In one or more embodiments of the present disclosure, the movable mechanical part includes a rotatable joint of the robotic arm, and the air particle detector is located underneath or next to the rotatable joint.

In one or more embodiments of the present disclosure, the robotic arm includes an arm portion and a linear motion mechanism configured to move the arm portion. The movable mechanical part includes the linear motion mechanism, and the air particle detector is located underneath or next to the linear motion mechanism.

In one or more embodiments of the present disclosure, the protection action includes transitioning the wafer handling apparatus to a hold state. The control system is configured to transition the wafer handling apparatus to the hold state in response to a determination, based on the detection signal, that the number of particles in air exceeds a first threshold value.

In one or more embodiments of the present disclosure, the protection action further includes issuing a notice indicating presence of an anomaly. The control system is configured to issue the notice in response to a determination, based on the detection signal, that the number of particles in air exceeds a second threshold value. The second threshold value is less than the first threshold value.

In one or more embodiments of the present disclosure, the notice includes location information associated with the air particle detector.

In one or more embodiments of the present disclosure, the protection action further includes issuing a warning. The control system is configured to issue the warning in response to the determination that the number of particles in air exceeds the first threshold value. The warning includes location information associated with the air particle detector.

In one or more embodiments of the present disclosure, the control system includes a processor and a data storage device. The data storage device is configured to store an operating schedule of the wafer handling apparatus. The processor is configured to determine a time at which the number of particles in air exceeds a first threshold value based on the detection signal. The processor is further configured to identify a faulty mechanical part based on the operating schedule and the time at which the number of particles in air exceeds the first threshold value.

In accordance with an embodiment of the present disclosure, a method for monitoring a wafer handling apparatus includes: providing an air particle detector inside a housing of the wafer handling apparatus, in which the housing is configured to accommodate a robotic arm for moving a semiconductor wafer; providing, by the air particle detector, at least one detection signal indicative of a number of particles in air; receiving the at least one detection signal by a control system of the wafer handling apparatus; and performing, by the control system, at least one protection action based on the at least one detection signal.

In one or more embodiments of the present disclosure, the air particle detector is located at a first location or a second location. The first location is underneath a path along which the robotic arm moves the semiconductor wafer. The second location is underneath or next to a movable mechanical part of the wafer handling apparatus.

In one or more embodiments of the present disclosure, performing the at least one protection action includes transitioning the wafer handling apparatus to a hold state in response to a determination, based on the at least one detection signal, that the number of particles in air exceeds a first threshold value.

In one or more embodiments of the present disclosure, performing the at least one protection action further includes issuing a notice indicating presence of an anomaly in response to a determination, based on the at least one detection signal, that the number of particles in air exceeds a second threshold value. The second threshold value is less than the first threshold value.

In one or more embodiments of the present disclosure, performing the at least one protection action further includes issuing a warning in response to the determination that the number of particles in air exceeds the first threshold value. The warning includes location information associated with the air particle detector.

In one or more embodiments of the present disclosure, the method further includes: determining, by the control system, a time at which the number of particles in air exceeds a first threshold value based on the at least one detection signal; and identifying, by the control system, a faulty mechanical part of the wafer handling apparatus based on an operating schedule of the wafer handling apparatus and the time at which the number of particles in air exceeds the first threshold value.

In sum, the present disclosure provides a technique for monitoring particle generation inside the wafer handling apparatus, which could be caused by a faulty component of the wafer handling apparatus. The monitoring of particle generation can be done in real-time. Specifically, at least one air particle detector is provided in the interior of the housing of the wafer handling apparatus. The air particle detector can provide at least one detection signal indicative of a number of particles in air. The control system of the wafer handling apparatus can receive the detection signal and perform at least one protection action based on the detection signal. In an embodiment, the control system can transition the wafer handling apparatus to a hold state in response to a determination that the number of particles in air exceeds a threshold value, so as to prevent contamination of additional wafers. The control system can also issue a warning to notify the staff of the fabrication facility to examine the wafer handling apparatus and replace or repair the faulty component.

It is to be understood that both the foregoing general description and the following detailed description are by examples, and are intended to provide further explanation of the disclosure as claimed.

### BRIEF DESCRIPTION OF THE DRAWINGS

To make the objectives, features, advantages, and embodiments of the present disclosure, including those mentioned above and others, more comprehensible, descriptions of the accompanying drawings are provided as follows.

FIG. 1 illustrates an isometric view of a wafer handling apparatus in accordance with an embodiment of the present disclosure;

FIG. 2 illustrates a schematic top view of the interior of the wafer handling apparatus shown in FIG. 1, in which one of the load ports receives a wafer container;

FIG. 3 illustrates a schematic side view of the interior of the wafer handling apparatus shown in FIG. 1, in which one of the load ports receives a wafer container;

FIG. 4 illustrates a schematic block diagram of the wafer handling apparatus shown in FIG. 1; and

FIG. 5 illustrates an example of a particle monitoring chart and an example of an operating schedule of the wafer handling apparatus.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

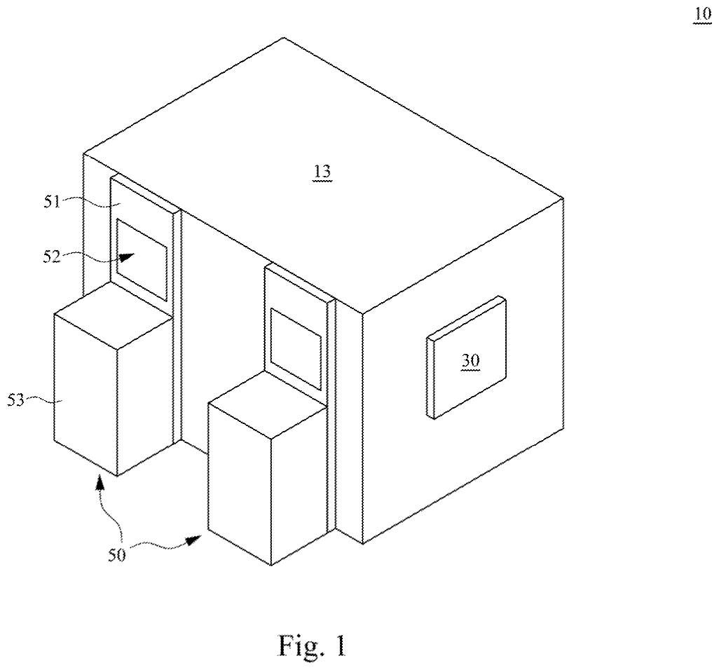

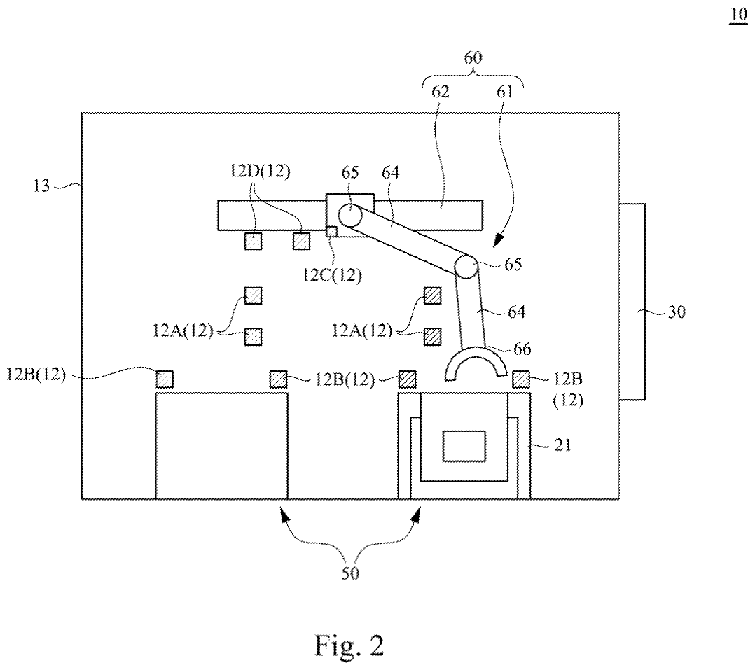

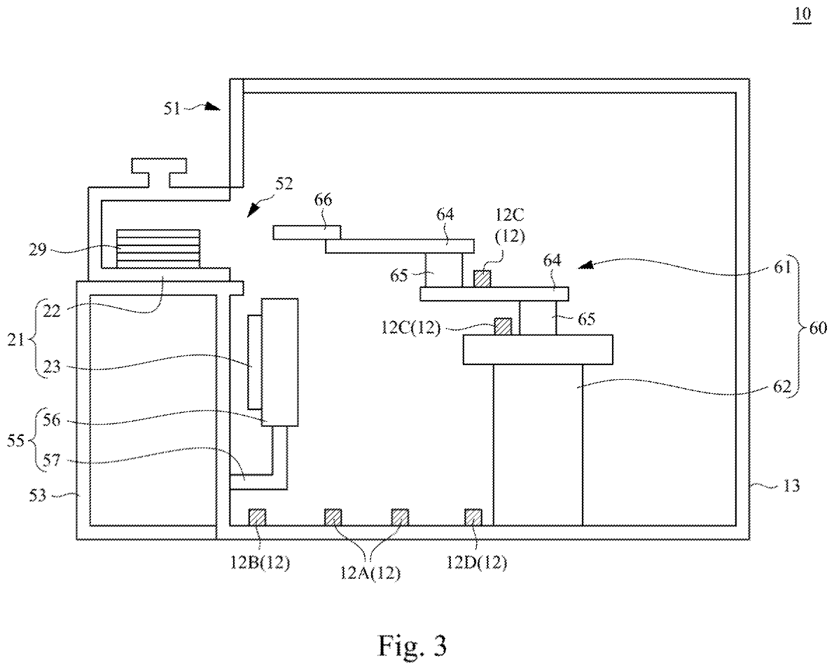

Reference is made to FIG. 1. FIG. 1 illustrates an isometric view of a wafer handling apparatus 10 in accordance with an embodiment of the present disclosure. The wafer handling apparatus 10 includes a housing 13 and one or more load ports 50. The housing 13 houses various components of the wafer handling apparatus 10, such as a robotic arm (will be introduced later), a device for processing semiconductor wafers (e.g., a device that performs etching, deposition, or polishing operation on semiconductor wafers), and etc. The load ports 50 are mounted on a side of the housing 13, and each of the load ports 50 is configured to receive a wafer container (e.g., the wafer container 21 shown in FIGS. 2 and 3). The wafer container is configured to accommodate one or more semiconductor wafers. The wafer container is, for example, a front opening unified pod (FOUP). In some embodiments, the wafer handling apparatus 10 is a wafer transferring apparatus for moving semiconductor wafers (e.g., an equipment front-end module (EFEM)). In some embodiments, the wafer handling apparatus 10 is a wafer processing apparatus for processing semiconductor wafers.

As shown in FIG. 1, the wafer handling apparatus 10 further includes a control system 30. The control system 30 is configured to control the operations of various components of the wafer handling apparatus 10, such as the load ports 50, a robotic arm (will be introduced later), and etc. The control system 30 may also monitor the wafer handling apparatus 10. The control system 30 may also display information about the wafer handling apparatus 10. The control system 30 may be provided on a side of the housing 13, or may be provided inside the housing 13.

Reference is made to FIGS. 2 and 3. FIG. 2 illustrates a schematic top view of the interior of the wafer handling apparatus 10 shown in FIG. 1, in which one of the load ports 50 receives a wafer container 21. FIG. 3 illustrates a schematic side view of the interior of the wafer handling apparatus 10 shown in FIG. 1, in which one of the load ports 50 receives a wafer container 21. The wafer container 21 includes a main body 22 having an internal space for storing one or more semiconductor wafers 29 (e.g., silicon wafers). The wafer container 21 also includes a door 23 configured to cover one side of the main body 22 to close the internal space of the main body 22.

As shown in FIGS. 2 and 3, each of the load ports 50 includes a front panel 51 and a platform 53. The front panel 51 has an opening 52 communicating with an internal space of the housing 13. The semiconductor wafers 29 can be transferred into or out of the housing 13 through the opening 52. The platform 53 is positioned below the opening 52 and is configured to support the wafer container 21. The wafer container 21 may be placed on the platform 53 by an overhead hoist transport (OHT) system of a semiconductor fabrication facility.

As shown in FIGS. 2 and 3, each of the load ports 50 further includes a door opening device 55 configured to open the door 23 of the wafer container 21 received by the load ports 50. In some embodiments, the door opening device 55 includes a door holder 56 and a driving mechanism 57. The door holder 56 is configured to fixedly engage the door 23 of the wafer container 21. The driving mechanism 57 is connected to the door holder 56 and is configured to move the door holder 56.

For example, during a door opening operation, after the door holder 56 engages with the door 23 of the wafer container 21, the driving mechanism 57 can move the door holder 56 along with the door 23 downward to separate the door 23 from the main body 22 to allow access to the internal space of the main body 22. For example, during a door closing operation, the driving mechanism 57 can first move the door holder 56 along with the door 23 upward to attach the door 23 to the main body 22. Once the door 23 is attached to the main body 22, the door holder 56 can release the door 23.

As shown in FIGS. 2 and 3, the wafer handling apparatus 10 further includes a robotic arm 60. The robotic arm 60 is disposed inside the housing 13 and is positioned to face the load ports 50. The robotic arm 60 is configured to transfer the semiconductor wafers 29 into or out of the wafer container 21. In some embodiments, the robotic arm 60 can transfer the semiconductor wafers 29 from the wafer container 21 to one or more wafer processing devices in the housing 13 for processing of the semiconductor wafers 29. In some embodiments, the robotic arm 60 can transfer the semiconductor wafers 29 from the one or more wafer processing devices back to the wafer container 21 after the semiconductor wafers 29 have been processed.

As shown in FIGS. 2 and 3, in some embodiments, the robotic arm 60 includes an arm portion 61 and a linear motion mechanism 62. The linear motion mechanism 62 is connected to the arm portion 61 and is configured to move the arm portion 61. For example, in the illustrated embodiment, the linear motion mechanism 62 can move the arm portion 61 horizontally within the housing 13. The linear motion mechanism 62 may be mounted on a floor portion of the housing 13 and positioned below the arm portion 61, as illustrated in FIG. 3. Alternatively, the linear motion mechanism 62 may be mounted on a ceiling portion of the housing 13.

As shown in FIGS. 2 and 3, in some embodiments, the arm portion 61 of the robotic arm 60 includes a plurality of rotatable links 64 interconnected by one or more rotatable joints 65. The rotatable links 64 can rotate about a vertical axis to move the semiconductor wafers 29 into or out of the wafer container 21. In some embodiments, the arm portion 61 further includes a wafer support 66 disposed on a terminal end of the uppermost rotatable link 64 and configured to support the semiconductor wafers 29.

As shown in FIGS. 2 and 3, the wafer handling apparatus 10 further includes at least one air particle detector 12. The air particle detector 12 is disposed inside the housing 13 and is configured to detect particles of a specific size class (or particles of two or more size classes; for example, particles having a diameter of 0.3 micrometer or 0.5 micrometer) in the internal space of housing 13. The air particle detector 12 is configured to provide at least one detection signal indicative of a number of particles in air (in the internal space of housing 13).

As shown in FIGS. 2 and 3, the control system 30 is communicably coupled to the air particle detector 12 and is configured to receive the detection signal from the air particle detector 12. For example, the control system 30 can receive the detection signal from the air particle detector 12 periodically (e.g., receive the detection signal every second). The control system 30 is further configured to perform at least one protection action based on the detection signal provided by the air particle detector 12. By this arrangement, if there exists any faulty mechanical part within the wafer handling apparatus 10 (e.g., a faulty door opening device, a faulty robotic arm, etc.) generating particles that could contaminate the semiconductor wafers 29, the control system 30 can timely detect the change of the environmental condition within the wafer handling apparatus 10 and take measure to minimize damage.

As shown in FIGS. 2 and 3, in some embodiments, the wafer handling apparatus 10 includes at least one air particle detector 12A located underneath a path along which the robotic arm 60 moves the semiconductor wafers 29. By this arrangement, the control system 30, which receives the detection signal from the air particle detector 12A, can determine whether the semiconductor wafers 29 have moved through a contaminated area.

As shown in FIGS. 2 and 3, in some embodiments, the path along which the robotic arm 60 moves the semiconductor wafer 29 includes a path between the linear motion mechanism 62 and the load ports 50. In such embodiments, the air particle detector 12A may be provided at a location between the linear motion mechanism 62 and the load ports 50.

As shown in FIGS. 2 and 3, in some embodiments, the wafer handling apparatus 10 includes at least one air particle detector 12 located underneath or next to a movable mechanical part of the wafer handling apparatus 10 (e.g., the robotic arm 60 or the door opening device 55). By this arrangement, in an event that the movable mechanical part fails and starts to generate particles, the control system 30, which receives the detection signal from the air particle detector 12, can timely detect such an event.

As shown in FIGS. 2 and 3, in some embodiments, the wafer handling apparatus 10 includes one or more air particle detectors 12B located underneath or next to the door opening device 55. In some embodiments, two air particle detectors 12B are provided on the left side and the right side of each load port 50, respectively.

As shown in FIGS. 2 and 3, in some embodiments, the wafer handling apparatus 10 includes at least one air particle detector 12C located underneath or next to the rotatable joints 65 of the robotic arm 60. In some embodiments, the wafer handling apparatus 10 includes one or more air particle detectors 12D underneath or next to the linear motion mechanism 62. In some embodiments, the air particle detectors 12D are arranged along a rail of the linear motion mechanism 62.

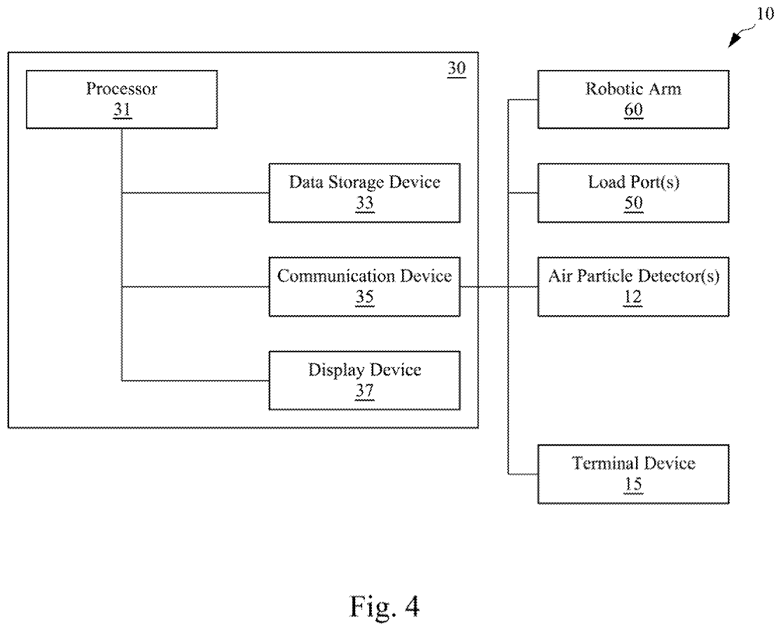

Reference is made to FIG. 4. FIG. 4 illustrates a schematic block diagram of the wafer handling apparatus 10 shown in FIG. 1. In some embodiments, the control system 30 includes a communication device 35 (e.g., a network interface controller) configured to send and receive signals (e.g., electronic signals). The communication device 35 is connected to the air particle detector 12 and is configured to receive the detection signal from the air particle detector 12. The communication device 35 may also be connected to a terminal device 15 (e.g., a desktop computer or a portable electronic device operated by a staff of a fabrication facility) and enable the control system 30 to communicate with the terminal device 15. The communication device 35 may also be connected to the load ports 50 and the robotic arm 60. The control system 30 can send commands (e.g., control signals) to the load ports 50 and the robotic arm 60 via the communication device 35.

As shown in FIG. 4, in some embodiments, the control system 30 further includes a processor 31 configured to execute computational tasks, such as analyzing the detection signal output by the air particle detector 12, generating commands, and etc. In some embodiments, the control system 30 further includes a data storage device 33 configured to store data associated with the wafer handling apparatus 10. In some embodiments, the control system 30 further includes a display device 37 configured to display information.

As mentioned above, the control system 30 is configured to perform at least one protection action based on the detection signal provided by the air particle detector 12. In some embodiments, the protection action includes transitioning the wafer handling apparatus 10 to a hold state, in which various components of the wafer handling apparatus 10, such as the load ports 50, the robotic arm 60 and any wafer processing device included in the wafer handling apparatus 10, cease operation. The control system 30 is configured to transition the wafer handling apparatus 10 to the hold state in response to a determination, based on the detection signal, that the number of particles in air exceeds a first threshold value. In some embodiments, the processor 31 can convert the received detection signal to a numerical value showing the number of particles detected by the air particle detector 12 at a particular time, and then compare the numerical value to the first threshold value to determine if the number of particles in air exceeds the first threshold value.

In some embodiments, the protection action further includes issuing a warning. The control system 30 is configured to issue the warning in response to the determination that the number of particles in air exceeds the first threshold value. In some embodiments, the warning includes a warning message displayed on the display device 37. In some embodiments, the warning includes a warning message (e.g., an email) sent to the terminal device 15. In some embodiments, the warning includes an audio alarm created by an alarm system (not depicted) of the wafer handling apparatus 10.

In some embodiments, the warning includes location information associated with the air particle detector 12. In some embodiments, the wafer handling apparatus 10 includes a plurality of air particle detectors 12, and the control system 30 stores a lookup table of the location information of each air particle detector 12 (e.g., stored in the data storage device 33). The lookup table can be represented using any suitable data structure, such an associative array, a hash table, a database table, and etc. When the control system 30 discovers that the detection signal provided by a particular air particle detector 12 indicates the number of particles in air exceeding the first threshold value, the control system 30 can obtain the location information of the particular air particle detector 12 from the lookup table and include the location information in the warning. As a result, the staff of the fabrication facility can quickly identify the cause of the generation of particles and resolve it.

In some embodiments, the protection action further includes issuing a notice indicating presence of an anomaly. The control system 30 is configured to issue the notice in response to a determination, based on the detection signal, that the number of particles in air exceeds a second threshold value. The second threshold value is less than the first threshold value. By this arrangement, an issue within the wafer handling apparatus 10 can be identified at an early stage to reduce the downtime of the wafer handling apparatus 10 and minimize the amount of wafers being contaminated.

In some embodiments, the notice can be displayed on the display device 37 or sent to the terminal device 15. In some embodiments, the notice includes location information associated with the air particle detector 12. In some embodiments, when the control system 30 discovers that the detection signal provided by a particular air particle detector 12 indicates the number of particles in air exceeding the second threshold value, the control system 30 can obtain the location information of the particular air particle detector 12 from the lookup table mentioned above and include the location information in the notice.

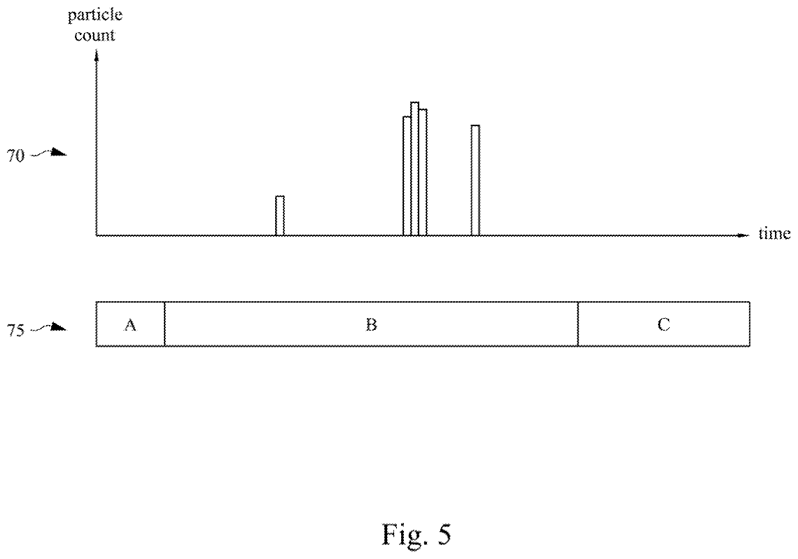

Reference is made additionally to FIG. 5. FIG. 5 illustrates an example of a particle monitoring chart 70 and an example of an operating schedule 75 of the wafer handling apparatus 10. As shown in FIGS. 4 and 5, in some embodiments, the processor 31 of the control system 30 is configured to generate the particle monitoring chart 70 based on a plurality of detections signals received from the at least one air particle detector 12 over a period of time. The horizontal axis of the particle monitoring chart 70 is time, and the vertical axis of the particle monitoring chart 70 is particle count, i.e., the number of particles detected by the air particle detector 12. The particle monitoring chart 70 can be displayed on the display device 37, or the particle monitoring chart 70 can be sent to the terminal device 15 and displayed on the terminal device 15.

As shown in FIGS. 4 and 5, in some embodiments, the data storage device 33 is configured to store the operating schedule 75 of the wafer handling apparatus 10. The operating schedule 75 may include a plurality of tasks (tasks A, B and C in this simplified example) performed by various components of the wafer handling apparatus 10. The tasks may be sorted by time (e.g., sorted by the starting time of each task). The operating schedule 75 can be represented using any suitable data structure, such an array.

As shown in FIGS. 4 and 5, in some embodiments, the processor 31 of the control system 30 is configured to determine a time at which the number of particles in air exceeds a threshold value (can be either the first threshold value or the second threshold value mentioned above) based on the detections signal received from the at least one air particle detector 12. The processor 31 is further configured to identify at least one faulty mechanical part based on the operating schedule 75 and the time at which the number of particles in air exceeds the threshold value.

As shown in FIGS. 4 and 5, in some embodiments, the processor 31 is configured to identify at least one ongoing task of in the operating schedule 75 at the time at which the number of particles in air exceeds the threshold value, and identify at least one mechanical part involved in the identified ongoing task as the at least one faulty mechanical part. The identified faulty mechanical part may be included in the warning or the notice mentioned above, such that the staff of the fabrication facility would be able to quickly identify the cause of the generation of particles and resolve it. In the example shown in FIG. 5, an abnormally large amount of particles (i.e., exceeding the threshold value) is detected by the air particle detector 12 when task B is being executed. Hence, at least one mechanical part involved in the task B is identified as faulty mechanical part.

In accordance with an embodiment of the present disclosure, a method for monitoring a wafer handling apparatus (e.g., the wafer handling apparatus 10 described above) includes: providing an air particle detector (e.g., the air particle detector 12 described above) inside a housing (e.g., the housing 13 described above) of the wafer handling apparatus, in which the housing is configured to accommodate a robotic arm (e.g., the robotic arm 60 described above) for moving a semiconductor wafer; providing, by the air particle detector, at least one detection signal indicative of a number of particles in air; receiving the at least one detection signal by a control system (e.g., the control system 30 described above) of the wafer handling apparatus; and performing, by the control system, at least one protection action based on the at least one detection signal. In some embodiments, the method further includes one or more of the operations performed by the wafer handling apparatus 10 described above.

In sum, the present disclosure provides a technique for monitoring particle generation inside the wafer handling apparatus, which could be caused by a faulty component of the wafer handling apparatus. The monitoring of particle generation can be done in real-time. Specifically, at least one air particle detector is provided in the interior of the housing of the wafer handling apparatus. The air particle detector can provide at least one detection signal indicative of a number of particles in air. The control system of the wafer handling apparatus can receive the detection signal and perform at least one protection action based on the detection signal. In an embodiment, the control system can transition the wafer handling apparatus to a hold state in response to a determination that the number of particles in air exceeds a threshold value, so as to prevent contamination of additional wafers. The control system can also issue a warning to notify the staff of the fabrication facility to examine the wafer handling apparatus and replace or repair the faulty component.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A wafer handling apparatus, comprising:
a housing;
a load port mounted on a side of the housing and configured to receive a wafer container, the wafer container being configured to accommodate a semiconductor wafer;
a robotic arm disposed inside the housing and configured to transfer the semiconductor wafer into or out of the wafer container;
an air particle detector disposed inside the housing and configured to provide at least one detection signal indicative of a number of particles in air; and
a control system communicably coupled to the air particle detector, the control system being configured to receive the at least one detection signal and perform at least one protection action based on the at least one detection signal.

2. The wafer handling apparatus of claim 1, wherein the air particle detector is located underneath a path along which the robotic arm moves the semiconductor wafer.

3. The wafer handling apparatus of claim 1, wherein the air particle detector is located underneath or next to a movable mechanical part of the wafer handling apparatus.

4. The wafer handling apparatus of claim 3, wherein the load port comprises a door opening device, the door opening device is configured to open a door of the wafer container received by the load port, wherein the movable mechanical part comprises the door opening device, and the air particle detector is located underneath or next to the door opening device.

5. The wafer handling apparatus of claim 3, wherein the movable mechanical part comprises a rotatable joint of the robotic arm, and the air particle detector is located underneath or next to the rotatable joint.

6. The wafer handling apparatus of claim 3, wherein the robotic arm comprises an arm portion and a linear motion mechanism configured to move the arm portion, wherein the movable mechanical part comprises the linear motion mechanism, and the air particle detector is located underneath or next to the linear motion mechanism.

7. The wafer handling apparatus of claim 1, wherein the at least one protection action comprises transitioning the wafer handling apparatus to a hold state, and wherein the control system is configured to transition the wafer handling apparatus to the hold state in response to a determination, based on the at least one detection signal, that the number of particles in air exceeds a first threshold value.

8. The wafer handling apparatus of claim 7, wherein the at least one protection action further comprises issuing a notice indicating presence of an anomaly, and wherein the control system is configured to issue the notice in response to a determination, based on the at least one detection signal, that the number of particles in air exceeds a second threshold value, and the second threshold value is less than the first threshold value.

9. The wafer handling apparatus of claim 8, wherein the notice comprises location information associated with the air particle detector.

10. The wafer handling apparatus of claim 7, wherein the at least one protection action further comprises issuing a warning, the control system is configured to issue the warning in response to the determination that the number of particles in air exceeds the first threshold value, and wherein the warning comprises location information associated with the air particle detector.

11. The wafer handling apparatus of claim 1, wherein the control system comprises a processor and a data storage device, the data storage device is configured to store an operating schedule of the wafer handling apparatus, the processor is configured to determine a time at which the number of particles in air exceeds a first threshold value based on the at least one detection signal, and the processor is configured to identify a faulty mechanical part based on the operating schedule and the time at which the number of particles in air exceeds the first threshold value.

12. A method for monitoring a wafer handling apparatus, the method comprising:
providing an air particle detector inside a housing of the wafer handling apparatus, wherein the housing is configured to accommodate a robotic arm for moving a semiconductor wafer;
providing, by the air particle detector, at least one detection signal indicative of a number of particles in air;
receiving the at least one detection signal by a control system of the wafer handling apparatus; and
performing, by the control system, at least one protection action based on the at least one detection signal.

13. The method of claim 12, wherein the air particle detector is located at a first location or a second location, the first location is underneath a path along which the robotic arm moves the semiconductor wafer, and the second location is underneath or next to a movable mechanical part of the wafer handling apparatus.

14. The method of claim 12, wherein performing the at least one protection action comprises transitioning the wafer handling apparatus to a hold state in response to a determination, based on the at least one detection signal, that the number of particles in air exceeds a first threshold value.

15. The method of claim 14, wherein performing the at least one protection action further comprises issuing a notice indicating presence of an anomaly in response to a determination, based on the at least one detection signal, that the number of particles in air exceeds a second threshold value, and wherein the second threshold value is less than the first threshold value.

16. The method of claim 14, wherein performing the at least one protection action further comprises issuing a warning in response to the determination that the number of particles in air exceeds the first threshold value, and wherein the warning comprises location information associated with the air particle detector.

17. The method of claim 12, further comprising:
determining, by the control system, a time at which the number of particles in air exceeds a first threshold value based on the at least one detection signal; and
identifying, by the control system, a faulty mechanical part of the wafer handling apparatus based on an operating schedule of the wafer handling apparatus and the time at which the number of particles in air exceeds the first threshold value.
